(19) United States
(12) Patent Application Publication
(10) Pub. No.: US 2025/0301923 A1
(43) Pub. Date: Sep. 25, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Bo-Han CHU, Taipei City (TW); Chin I WANG, Tainan City (TW); Yao-Wen CHANG, Taipei (TW)

(21) Appl. No.: 18/612,420

(22) Filed: Mar. 21, 2024

(51) Int. Cl. H10N 70/00; H10B 63/00; H10N 70/20

(52) U.S. Cl. CPC H10N 70/841; H10B 63/00; H10N 70/023; H10N 70/24; H10N 70/8833

(57) ABSTRACT

A resistive random access memory (RRAM) cell includes a bottom electrode that includes a high work function material. The high work function material enables the work function of the bottom electrode to be tuned such that a thinner and more conical conductive filament is formed in a resistive memory layer stack of the RRAM cell than without the high work function material. The conductive filament being thinner and more conical than without the high work function material enables the conductive filament to be formed using fewer oxygen vacancies than without the high work function material, which reduces the difficulty of combining oxygen vacancies in the resistive memory layer stack with oxygen atoms captured in a top electrode of the RRAM cell.

### BACKGROUND

A semiconductor device may include a non-volatile memory, which is able to store data in the absence of power. Non-volatile memory technologies include magneto-resistive random-access memory (MRAM), phase change random access memory (PC-RAM), and resistive random access memory (RRAM), among other examples. These non-volatile memory technologies are compatible with complementary metal-oxide-semiconductor (CMOS) logic fabrication processes, which enables logic and memory circuitry to be integrated onto the same semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example deposition tool described herein.

FIG. 2 is a diagram of a portion of an example semiconductor device described herein.

FIG. 3 is a diagram of an example implementation of a memory device included in a semiconductor device described herein.

FIGS. 4A and 4B are diagrams illustrating example implementations of operation of a memory device described herein.

FIGS. 5A-5K are diagrams of an example implementation of forming a memory device described herein.

FIG. 6 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A resistive random access memory (RRAM) cell may include a resistive memory layer stack between a bottom electrode and a top electrode. The RRAM cell may be selectively set to a low resistance state (LRS) or reset to a high resistance state (HRS). To set the RRAM cell to the LRS, a set operation may be performed in which a set voltage may be applied from the top electrode to the bottom electrode across the resistive memory layer stack. The set voltage causes oxygen atoms in one or more layers of the resistive memory layer stack to be captured in the top electrode, resulting in formation of oxygen vacancies in the resistive memory layer stack. An electric field from the set voltage causes the oxygen vacancies to migrate toward the bottom electrode and to form a conductive filament (CF) at the bottom of the resistive memory layer stack. Forming the conductive filament transitions the resistive memory layer stack (and thus, the RRAM cell) to the LRS.

To reset the RRAM cell, a reset operation may be performed in which a reset voltage may be applied from the top electrode to the bottom electrode. The reset voltage reverses the process by which the conductive filament is formed such that the oxygen atoms in the top electrode combine with the oxygen vacancies in the conductive filament in the resistive memory layer stack. The oxygen recombination of the oxygen atoms with the oxygen vacancies transitions the resistive memory layer stack (and thus, the RRAM cell) to the HRS.

Various techniques may be used to increase the operating efficiency of an RRAM cell. One technique includes using a lesser set voltage and/or a lesser reset voltage for switching the RRAM cell between the LRS and the HRS. A lesser set voltage and/or a lesser reset voltage may reduce the power consumption of the RRAM cell, which may increase the operating efficiency of an RRAM cell. The RRAM cell may be formed to include a more active top electrode to enable the RRAM cell to operate at a lesser set voltage and/or a lesser reset voltage. The top electrode may be more active in that the top electrode may more actively capture oxygen atoms from the resistive memory layer stack, thereby enabling the conductive filament to be more readily formed in the resistive memory layer stack. However, the lesser reset voltage may cause endurance issues for the RRAM cell in that the lesser reset voltage may not as effectively facilitate oxygen recombination in the resistive memory layer stack as a greater reset voltage. As a result, residual oxygen vacancies may be retained in the resistive memory layer stack, resulting in an increased reset failure bit count (FBC) as set-reset cycles are accumulated for the RRAM cell. The increased FBC may result in reduced reliability and reduced endurance for the RRAM cell.

In some implementations described herein, an RRAM cell includes a bottom electrode that includes a high work function material. The high work function material enables the work function of the bottom electrode to be tuned such that a thinner and more conical conductive filament is formed in a resistive memory layer stack of the RRAM cell than without the high work function material. The conductive filament being thinner than without the high work function material enables the conductive filament to be formed using fewer oxygen vacancies than without the high work function material, which reduces the difficulty of combining oxygen vacancies in the resistive memory layer stack with oxygen atoms captured in a top electrode of the RRAM cell. Additionally and/or alternatively the conical shape of the conductive filament results from fewer oxygen vacancies near the bottom electrode, which further reduces difficulty of combining oxygen vacancies in the resistive memory layer stack with oxygen atoms captured in a top electrode of the RRAM cell, in that the oxygen atoms do not need to travel as far down into the resistive memory layer stack. Accordingly, the high work function material of the bottom electrode described herein enables a more complete oxygen recombination to be achieved during a reset operation of the RRAM cell.

In this way, the high work function material of the bottom electrode described herein reduces the likelihood of residual oxygen vacancies being retained in the resistive memory layer stack, which results in a reduced reset failure bit count (FBC) for the RRAM cell. The reduced FBC may enable increased reliability and/or increased endurance to be achieved for the RRAM cell. Additionally and/or alternatively, the high work function material of the bottom electrode described herein may include lower cost materials relative to other types of bottom electrode materials such as ruthenium (Ru), which may reduce the manufacturing cost for forming the RRAM cell.

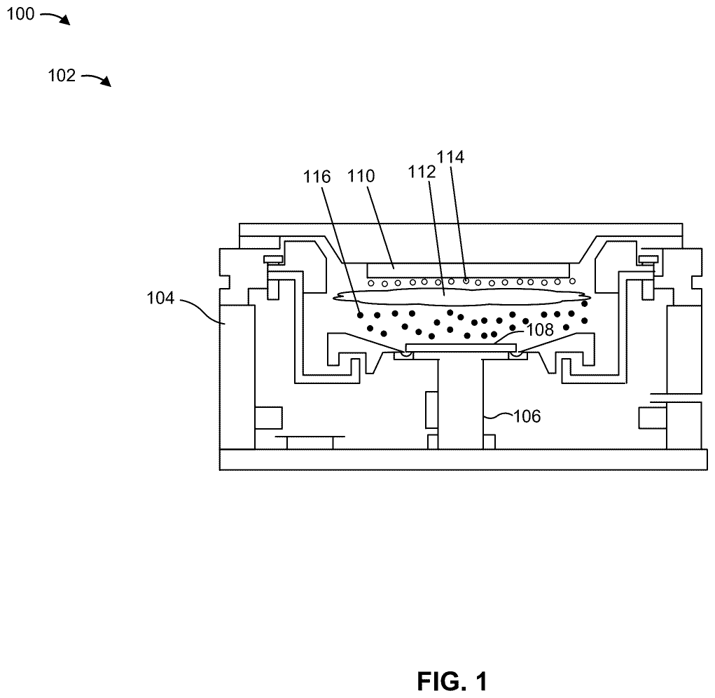

FIG. 1 is a diagram of an example implementation 100 of a deposition tool 102 described herein. The example deposition tool 102 illustrated in FIG. 1 includes a physical vapor deposition (PVD) tool such as a sputtering tool. The deposition tool 102 includes a processing chamber 104 and a pedestal component 106 on which a chuck 108 (e.g., an electrostatic chuck (ESC) or a vacuum chuck, among other examples) is supported. In some implementations, the pedestal component 106 includes a heating component (e.g., a hot plate, among other examples) to provide heat to a semiconductor substrate on the chuck 108 during a deposition operation (e.g., a PVD operation, a sputtering operation) performed by the deposition tool 102.

A material target 110 may be positioned in the processing chamber 104 of the deposition tool 102. The material target 110 may be included above the chuck 120 such that material may be sputtered from the material target 110 to deposit material from the material target 110 onto a semiconductor substrate that is on the chuck 108.

During operation of the deposition tool 102, a plasma 112 may be formed in the processing chamber 104 using a process gas 114 such as nitrogen (N), krypton (Kr), argon (Ar), and/or another gas. The plasma 112 may be used to bombard the material target 110 with ions to remove sputtered material 116 from the material target 110. One or more electrical bias voltages may be applied to the material target 110 and or the pedestal component 106. An electrical bias may be applied to the material target 110 to cause the ions in the plasma 112 to accelerate toward the material target 110 to sputter etch the material target 110. This causes the sputtered material 116 to be dislodged and mobilized. An electrical bias may be applied to the pedestal component 106 to generate an electrical potential or electric field between the material target 110 and the semiconductor substrate on the chuck 108. This promotes or facilitates a flow of sputtered material 116 from the material target 110 toward the semiconductor substrate.

In some implementations, one or more semiconductor processing tools, such as the deposition tool 102, may be used to perform one or more semiconductor processing operations described herein. For example, one or more semiconductor processing tools may be used to form a bottom electrode of a memory device in a semiconductor device, where the bottom electrode is formed of a chemically inert electrically conductive material having a work function that is greater than a work function of ruthenium (Ru); form a resistive memory layer of the memory device over the bottom electrode; and/or form a top electrode of the memory device over the resistive memory layer, among other examples.

As another example, one or more semiconductor processing tools may be used to form a bottom electrode of a memory device in a semiconductor device; form a resistive memory layer of the memory device over the bottom electrode; and/or form a top electrode of the memory device over the resistive memory layer, where forming the top electrode includes providing a nitrogen gas into a processing chamber of a deposition tool and generating a sputtered material from a material target in the processing chamber to deposit the sputtered material to form the top electrode, where the nitrogen gas is provided into the processing chamber at a flow rate that promotes a reaction between the nitrogen gas and the sputtered material, and resists a reaction between the nitrogen gas and the material target.

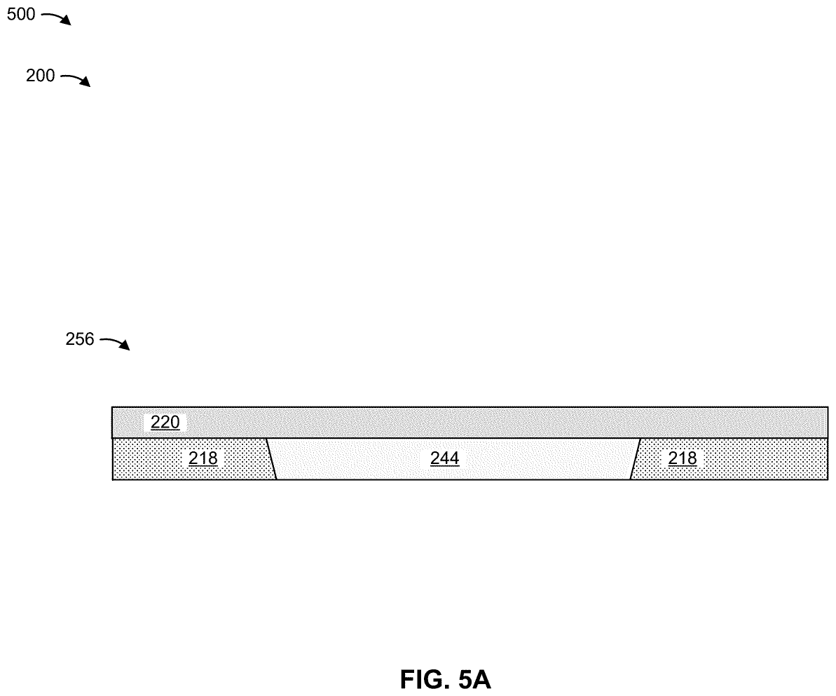

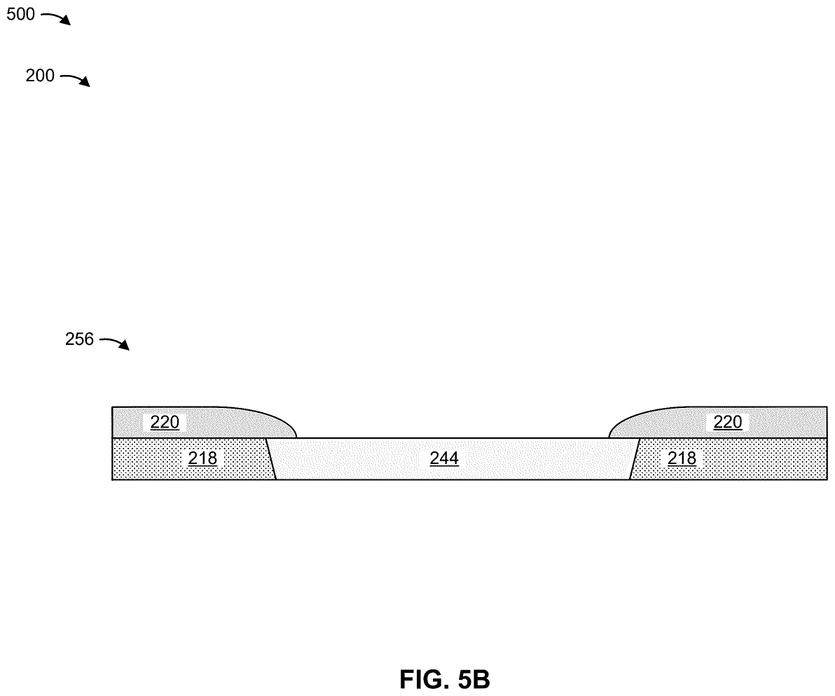

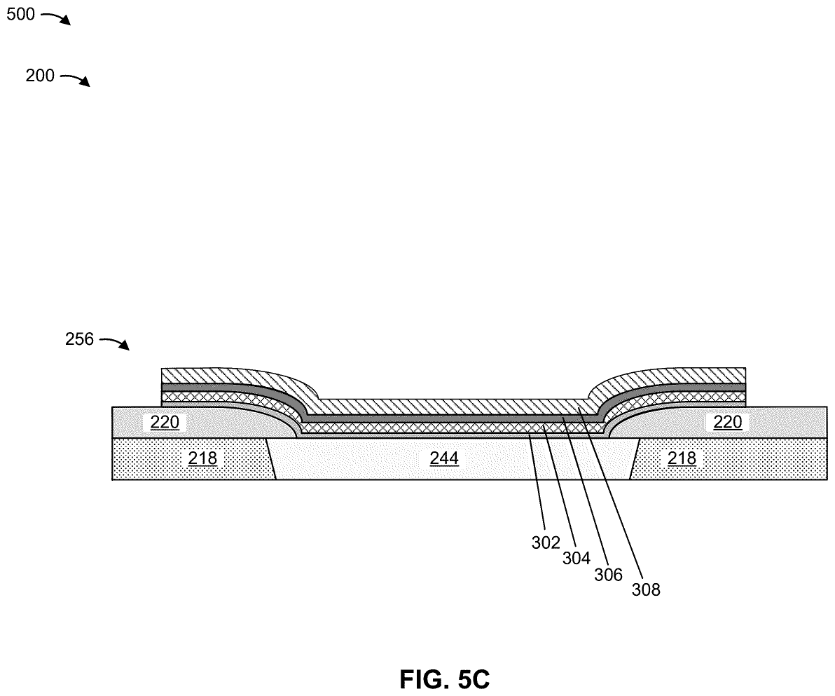

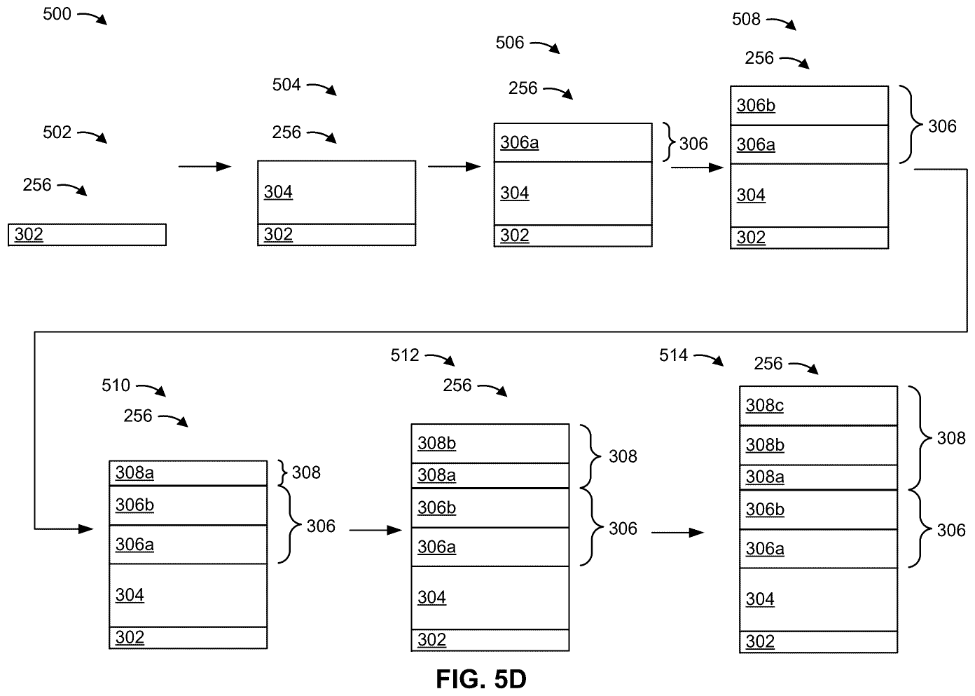

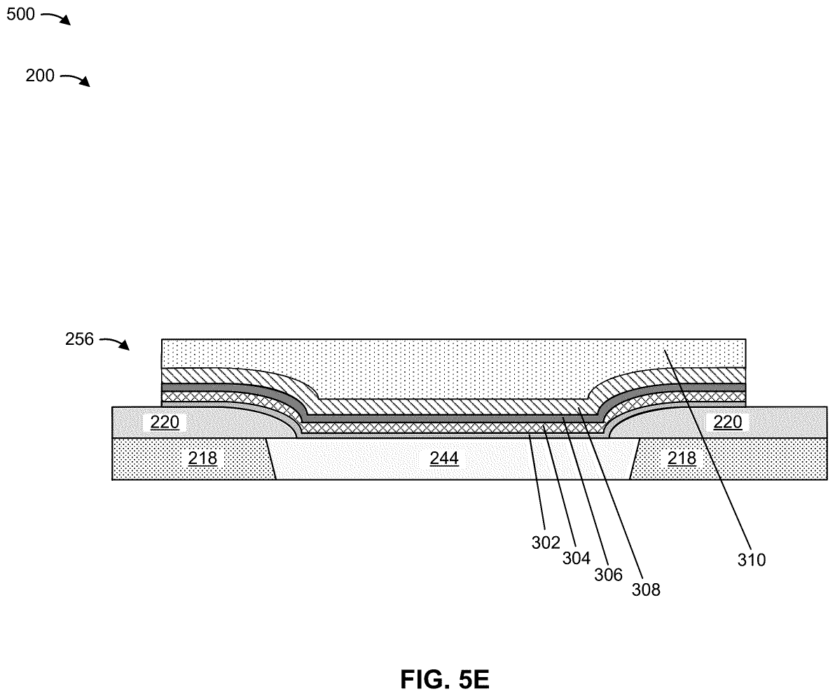

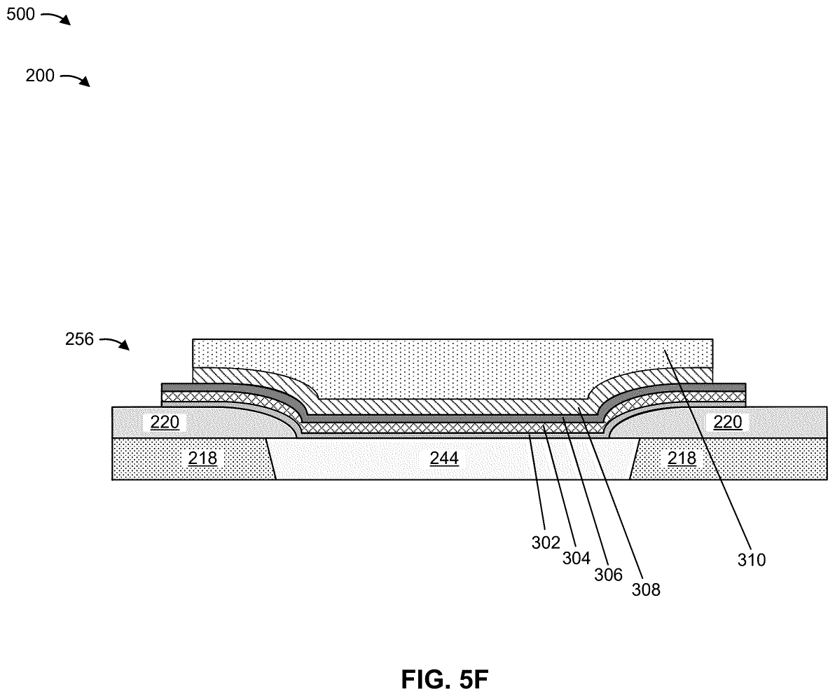

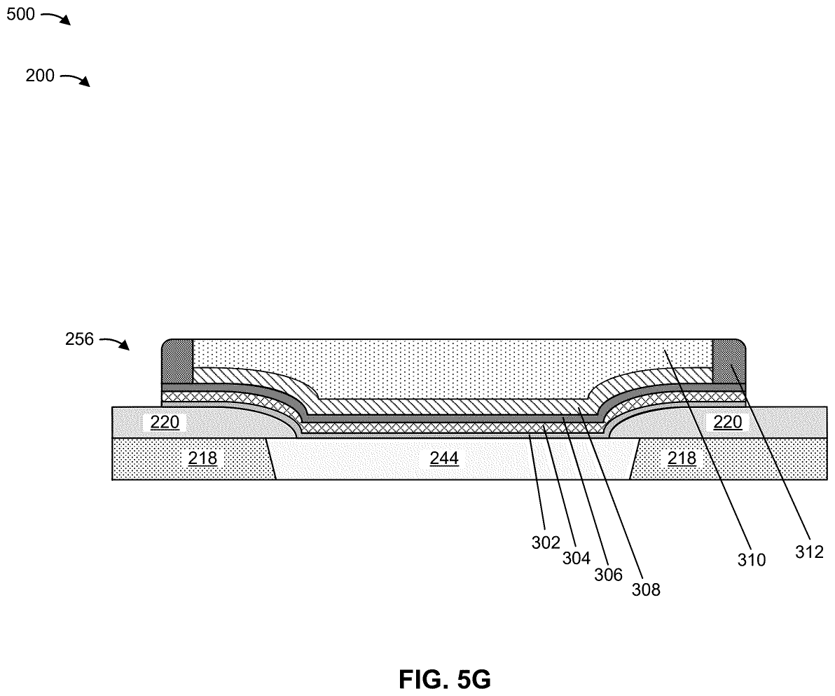

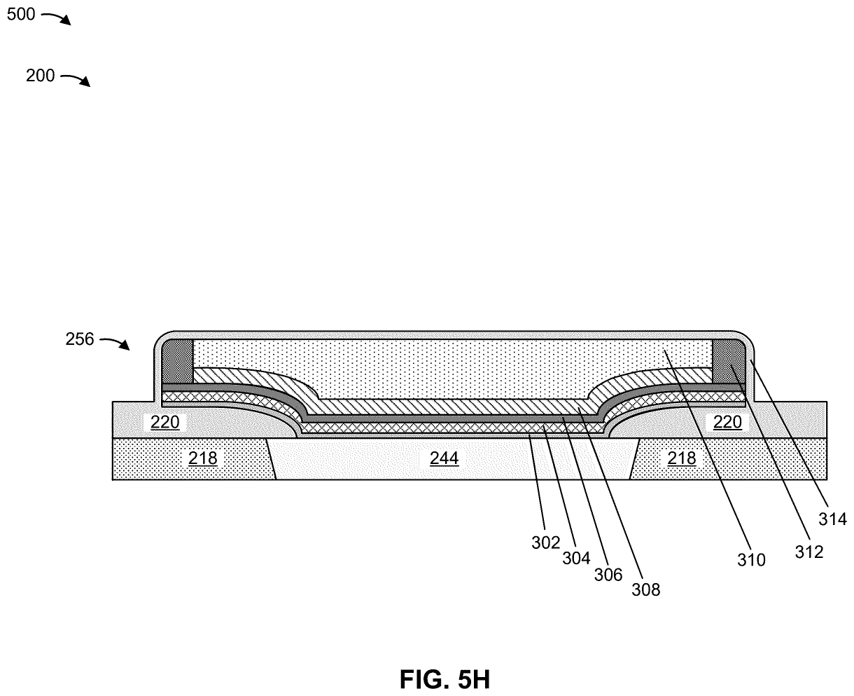

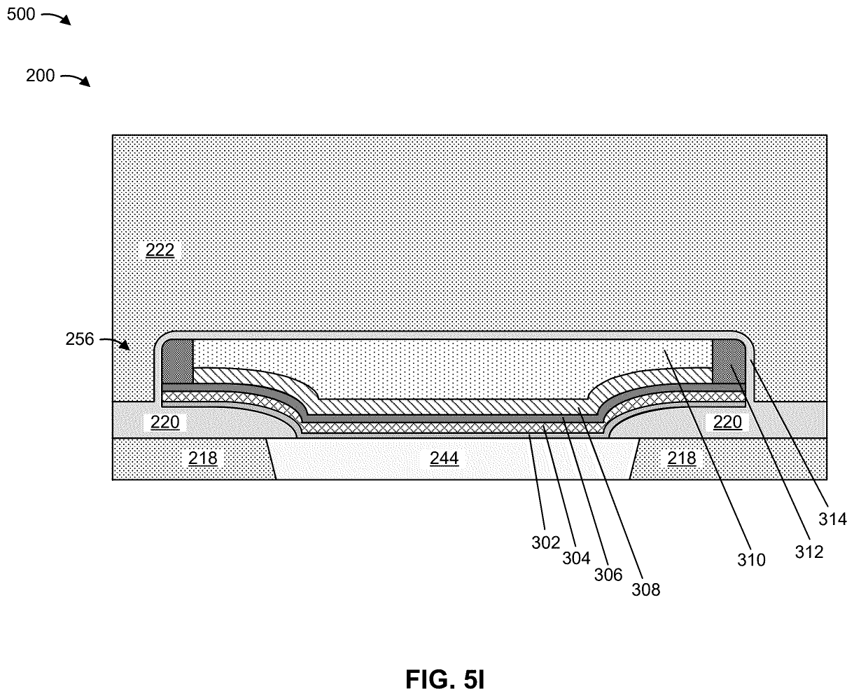

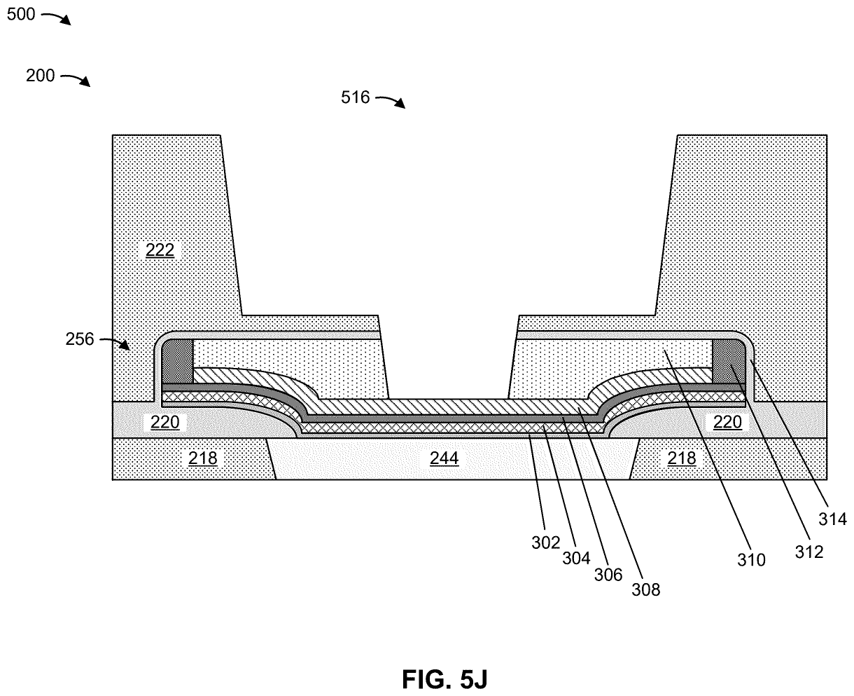

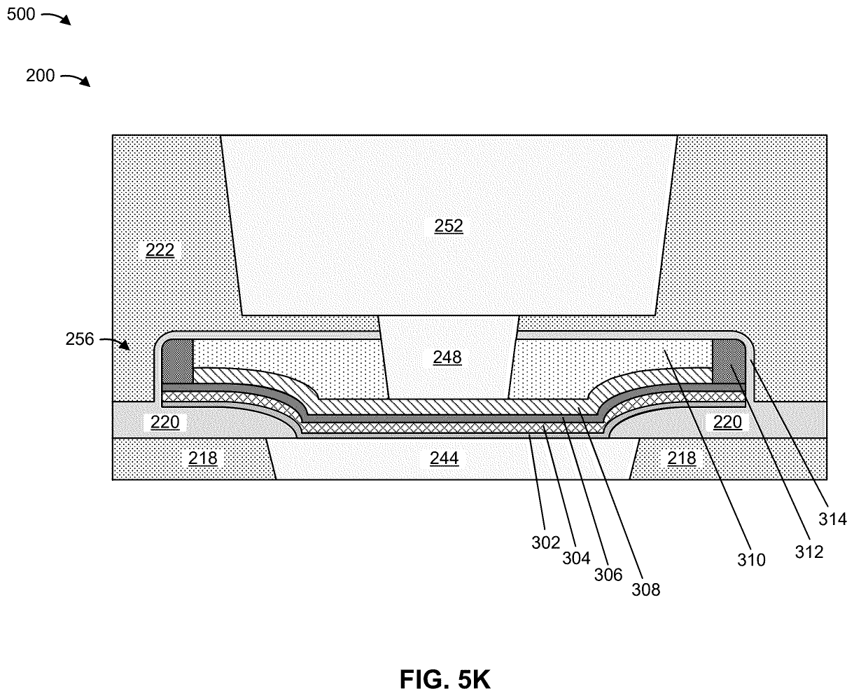

In some implementations, one or more semiconductor processing tools may be used to perform one or more semiconductor processing operations described in connection with FIGS. 5A-5K and/or 6, among other examples.

As indicated above, FIG. 1 is provided as an example. Other examples may differ from what is described with regard to FIG. 1.

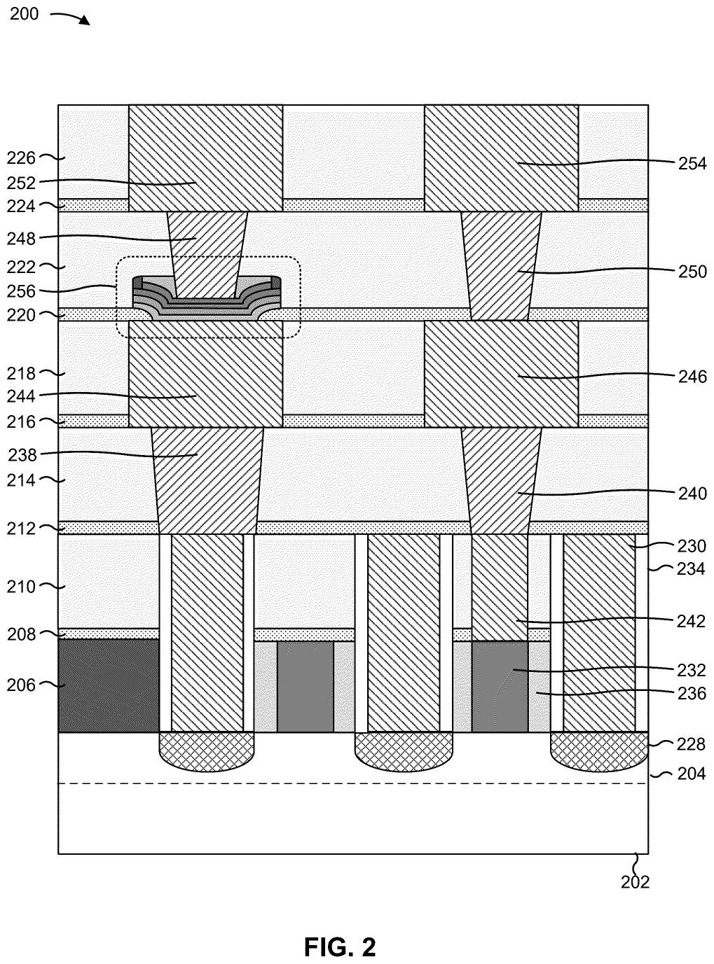

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM)), a semiconductor logic device, a processor, an input/output device, or another type of semiconductor device that includes one or more transistors.

The semiconductor device 200 includes one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source or drain regions of the transistors included in the semiconductor device 200.

The epitaxial regions 228 are electrically connected to metal source or drain contacts 230 of the transistors included in the semiconductor device 200. The metal source or drain contacts (MDs or CAs) 230 include cobalt (Co), ruthenium (Ru), and/or another conductive or metal material. The transistors further include gates 232 (MGs), which are formed of a polysilicon material, a metal (e.g., tungsten (W) or another metal), and/or another type of conductive material. The metal source or drain contacts 230 and the gates 232 are electrically isolated by one or more sidewall spacers, including spacers 234 in each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gates 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200.

The metal source or drain contacts 230 are electrically connected to source or drain interconnects 238 (e.g., source/drain vias or VDs). One or more of the gates 232 are electrically connected to gate interconnects 240 (e.g., gate vias or VGs). The interconnects 238 and 240 include a conductive material such as tungsten, cobalt, ruthenium, copper, and/or another type of conductive material. In some implementations, the gates 232 are electrically connected to the gate interconnects 240 by gate contacts 242 (CB or MP) to reduce contact resistance between the gates 232 and the gate interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of BEOL layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes vias 248 and 250. The V0 via layer is electrically connected to an M1 metallization that includes conductive structures 252 and 254. In some implementations, the BEOL layers of the semiconductor device 200 includes additional metallization layers and/or vias that connect the semiconductor device 200 to a package. The BEOL region of the semiconductor device 200 may refer to the region of the semiconductor device 200 above the ESL 208, including the structures/layers 210-226 and 238-254.

As further shown in FIG. 2, the semiconductor device 200 may include one or more devices and/or structures in the BEOL region of the semiconductor device 200. For example, the semiconductor device 200 may include one or more memory devices 256 (e.g., one or more BEOL memory devices) in the BEOL region of the semiconductor device 200. A memory device 256 may include, for example, a non-volatile memory device such as an RRAM device. The memory device 256 may be included between two or more backend metallization layers, such as between the conductive structure 244 and the via 248, among other examples. The conductive structure 244 may be electrically coupled and/or physically coupled with a bottom electrode of the memory device 256, and the via 248 may be electrically coupled and/or physically coupled with a top electrode of the memory device 256. The memory device 256 may be included in one or more backend dielectric layers in the BEOL region, such as in the ESL 220 and/or in the dielectric layer 222, among other examples.

As indicated above, FIG. 2 is provided as an example. Other examples may differ from what is described with regard to FIG. 2.

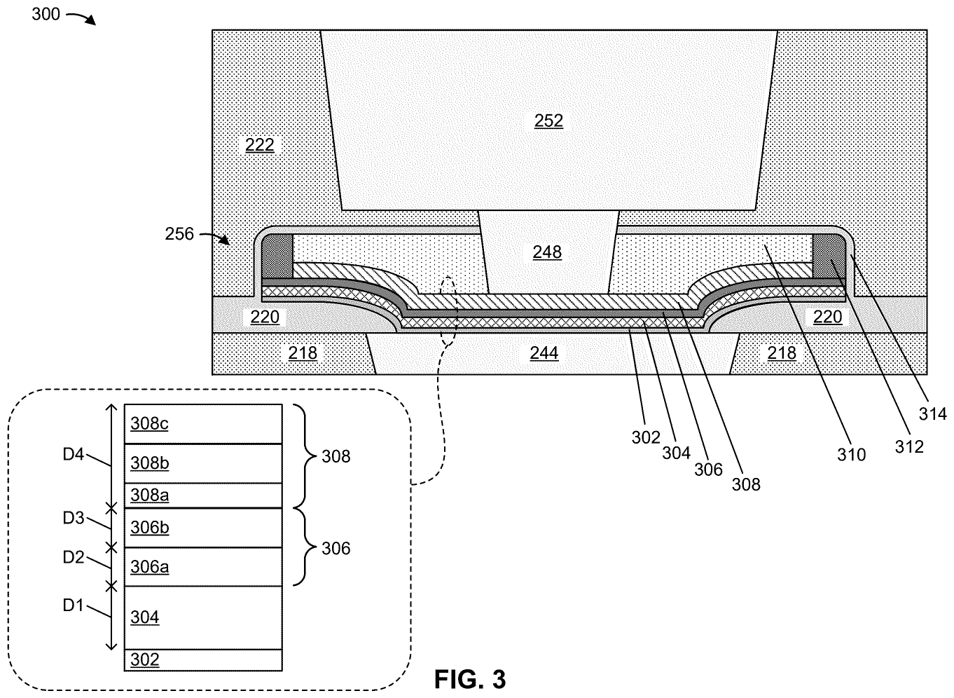

FIG. 3 is a diagram of an example implementation 300 of the memory device 256 included in the semiconductor device 200 described herein. As shown in FIG. 3, the memory device 256 includes a layer stack that is includes a flat section over and/or on the conductive structure 244, and curved sections that extend outward from the flat section. The curvature in the layer stack results from the process of exposing the conductive structure 244 through the ESL 220. The ESL 220 is etched to remove a portion of the ESL 220 over the conductive structure 244, resulting in rounded edges in the ESL 220.

The layer stack of the memory device 256 includes a barrier layer 302 over and/or on the conductive structure 244, a bottom electrode 304 over and/or on the barrier layer 302, a resistive memory layer 306 over and/or on the bottom electrode 304, and a top electrode 308 over and/or on the resistive memory layer 306. In some implementations, the barrier layer 302, the bottom electrode 304, the resistive memory layer 306, and/or the top electrode 308 extend over the rounded edges in the ESL 220, as shown in the example implementation 300 in FIG. 3. Alternatively, the portions of the barrier layer 302, the bottom electrode 304, the resistive memory layer 306, and/or the top electrode 308 over the rounded edges of the ESL 220 may be removed such that the layer stack of the memory device 256 includes only the flat section that is over the conductive structure 244.

To reset the RRAM cell, a reset operation may be performed in which a reset voltage may be applied from the top electrode to the bottom electrode. The reset voltage reverses the process by which the conductive filament is formed such that the oxygen atoms in the top electrode combine with the oxygen vacancies in the conductive filament in the resistive memory layer stack. The oxygen recombination of the oxygen atoms with the oxygen vacancies transitions the resistive memory layer stack (and thus, the RRAM cell) to the HRS.

The barrier layer 302 includes tantalum nitride (TaN), titanium nitride (TiN), and/or another material that resists migration of materials (e.g., copper) between the conductive structure 244 and the bottom electrode 304.

The bottom electrode 304 includes one or more electrically conductive materials. In some implementations, the bottom electrode 304 includes a metal material such as ruthenium (Ru), cobalt (Co), tantalum (Ta), titanium (Ti), and/or tungsten (W), among other examples. In some implementations, the bottom electrode 304 includes a chemically inert electrically conductive material, such as a metal nitride material.

In some implementations, the work function of the bottom electrode 304 is tuned to control oxygen vacancy formation in the bottom of the resistive memory layer 306 at the interface between the bottom electrode 304 and the resistive memory layer 306. For example, the chemically inert electrically conductive material of the bottom electrode 304 may include a chemically inert electrically conductive material having a high work function, such as a work function that is greater than a work function of ruthenium (Ru) (e.g., greater than approximately 4.7). The high work function of the chemically inert electrically conductive material of the bottom electrode 304 enables the bottom electrode 304 to resist absorption of oxygen atoms from the resistive memory layer 306, which enables a thin conductive filament to be formed in the resistive memory layer 306 at the interface between the resistive memory layer 306 and the bottom electrode 304.

In some implementations, the chemically inert electrically conductive material of the bottom electrode 304 includes molybdenum nitride (MoN), tungsten nitride (WN), and/or another electrically conductive nitride having a work function that is greater than approximately 4.7. In some implementations, the work function of the chemically inert electrically conductive material of the bottom electrode 304 is included in a range of approximately 4.9 to approximately 5.3. If the work function is less than approximately 4.9, the bottom electrode 304 may not be able to sufficiently block oxygen absorption from the resistive memory layer 306, and the conductive filament that is formed in the resistive memory layer 306 may have too high of a concentration of oxygen vacancies to fully recombine the oxygen vacancies. This may result in residual oxygen vacancies being retained in the resistive memory layer 306, which may decrease the endurance of the memory device 256 (e.g., may reduce the quantity of set-reset cycles that the memory device 256 can endure before failure) and/or may increase the reset FBC of the memory device 256. If the work function is greater than approximately 5.3, the memory device 256 may not be operable using lesser forming voltages. If the work function is included in the range of approximately 4.9 to approximately 5.3, the memory device 256 may be operated with lesser forming voltages while reducing the likelihood of residual oxygen vacancies being retained in the resistive memory layer 306. However, other values for the work function of the bottom electrode 304, and ranges other than approximately 4.9 to approximately 5.3, are within the scope of the present disclosure.

As shown in a close-up view of the layer stack of the memory device 256, the bottom electrode 304 may have a dimension D1 corresponding to a thickness of the bottom electrode 304. In some implementations, the dimension D1 is included in a range of approximately 30 angstroms to approximately 100 angstroms. If the dimension D1 is less than approximately 30 angstroms, logic data retention in the memory device 256 may suffer. If the dimension D1 is greater than approximately 100 angstroms, the height or thickness of the memory device 256 may be unnecessarily increased. If the dimension D1 is included in the range of approximately 30 angstroms to approximately 100 angstroms, the height or thickness of the memory device 256 may enable the memory device 256 to be included in smaller form-factor semiconductor devices while achieving a suitable logic data retention performance for the memory device 256. However, other values for the dimension D1, and ranges other than approximately 30 angstroms to approximately 100 angstroms, are within the scope of the present disclosure.

As further shown in the close-up view of the layer stack, the resistive memory layer 306 may include a resistive memory layer stack that includes a bottom resistive memory layer 306a over and/or on the bottom electrode 304, and a top resistive memory layer 306b over and/or on the bottom resistive memory layer 306a. The bottom resistive memory layer 306a and the top resistive memory layer 306b enable one or more properties of the resistive memory layer 306 to be tuned, such as a thickness of the resistive memory layer 306, a material composition of the resistive memory layer 306, and/or another property of the resistive memory layer 306, among other examples.

The bottom resistive memory layer 306a and the top resistive memory layer 306b may each include one or more resistive memory materials. The one or more resistive memory materials may include one or more high dielectric constant (high-k) dielectric materials, such as one or more dielectric materials having a dielectric constant that is greater than approximately 3.9. In some implementations, the bottom resistive memory layer 306a and the top resistive memory layer 306b each include an oxide-containing dielectric material, which enables the resistivity of the resistive memory layer 306 to be modified based on the absence or presence of oxygen vacancies in the resistive memory layer 306. Examples of high-k dielectric materials that may be included in the bottom resistive memory layer 306a and/or in the top resistive memory layer 306b include tantalum oxide (TaO), hafnium tantalum oxide (HfTaO), aluminum tantalum oxide (AlTaO), and/or another material that includes tantalum (Ta), oxygen (O), and/or one or more other elements.

In some implementations, the resistive memory material of the top resistive memory layer 306b includes a greater hafnium (Hf) concentration than the hafnium concentration in the resistive memory material of the bottom resistive memory layer 306a. Hafnium may have a higher oxygen affinity than other elements included in the resistive memory materials of the bottom resistive memory layer 306a and the top resistive memory layer 306b such as a tantalum. The greater concentration of hafnium in the top resistive memory layer 306b enables a greater amount of spontaneous oxygen to be captured in the top electrode 308 from the top resistive memory layer 306b than from the bottom resistive memory layer 306a. This enables a greater concentration of oxygen vacancies to be created in the top resistive memory layer 306b than in the bottom resistive memory layer 306a, which enables a tapered cross-sectional profile to be achieved for a conductive filament formed in the resistive memory layer 306. The tapered cross-sectional profile has a greater cross-sectional width at the top of the resistive memory layer 306 than at the bottom of the resistive memory layer 306, which increases the likelihood that the oxygen vacancies in the resistive memory layer 306 will be fully recombined with the spontaneous oxygen captured in the top electrode 308 when the conductive filament is dissipated than if the cross-sectional profile of the conductive filament had a uniform width.

In some implementations, the resistive memory material of the top resistive memory layer 306b has a greater ratio of high-k dielectric concentration to metal concentration than the resistive memory material of the bottom resistive memory layer 306a. For example, the resistive memory material of the top resistive memory layer 306a has a greater ratio of hafnium to tantalum (hafnium:tantalum or Hf:Ta) than the ratio of hafnium to tantalum in the resistive memory material of the bottom resistive memory layer 306a. Since hafnium has a higher oxygen affinity than tantalum, the greater ratio of hafnium to tantalum in the top resistive memory layer 306b enables a greater concentration of oxygen vacancies to form in the top resistive memory layer 306b than in the bottom resistive memory layer 306a.

In some implementations, a ratio of hafnium to tantalum ratio of the bottom resistive memory layer 306a is included in a range of approximately 1:3 to approximately 1:6. If the ratio is greater than approximately 1:3, the bottom resistive memory layer 306a may have too high of an oxygen affinity, which may result in lower rates of oxygen recombination in the bottom resistive memory layer 306a. If the ratio is less than approximately 1:6, the oxygen absorption in the top electrode 308 may not be sufficient for the memory device 256 to operate at lesser set voltages. If the ratio is included in the range of approximately 1:3 to approximately 1:6, the memory device 256 may be able to operate at lesser set voltages with reduced leakage and reduced rates of residual oxygen vacancies in the bottom resistive memory layer 306a. However, values for the ratio, and ranges other than approximately 1:3 to approximately 1:6, are within the scope of the present disclosure.

In some implementations, a hafnium to tantalum ratio of the top resistive memory layer 306b is included in a range of approximately 1:1 to approximately 1:2. If the ratio is greater than approximately 1:1, the top resistive memory layer 306b may have too high of an oxygen affinity, which may result in lower rates of oxygen recombination in the top resistive memory layer 306b. If the ratio is less than approximately 1:2, the oxygen absorption in the top electrode 308 may not be sufficient for the memory device 256 to operate at lesser set voltages. If the ratio is included in the range of approximately 1:1 to approximately 1:2, the memory device 256 may be able to operate at lesser set voltages with reduced leakage and reduced rates of residual oxygen vacancies in the top resistive memory layer 306b. However, values for the ratio, and ranges other than approximately 1:1 to approximately 1:2, are within the scope of the present disclosure.

As further shown in the close-up view of the layer stack of the memory device 256, the bottom resistive memory layer 306a may have a dimension D2 corresponding to a thickness of the bottom resistive memory layer 306a. In some implementations, the dimension D2 is included in a range of approximately 8 angstroms to approximately 30 angstroms. If the dimension D2 is lesser than approximately 8 angstroms, the memory device 256 may suffer from reduced endurance (e.g., may experience failure at a lesser quantity of set-reset cycles). If the dimension D2 is greater than approximately 30 angstroms, the memory device 256 may not operate at lesser set voltages. If the dimension D2 is included in the range of approximately 8 angstroms to approximately 30 angstroms, a low set voltage to be used for the memory device 256 while enabling a sufficient endurance performance to be achieved for the memory device 256. However, other values for the dimension D2, and ranges other than approximately 8 angstroms to approximately 30 angstroms, are within the scope of the present disclosure.

As further shown in the close-up view of the layer stack of the memory device 256, the top resistive memory layer 306b may have a dimension D3 corresponding to a thickness of the top resistive memory layer 306b. In some implementations, the dimension D3 is included in a range of approximately 8 angstroms to approximately 30 angstroms. If the dimension D3 is lesser than approximately 8 angstroms, the memory device 256 may suffer from increased current leakage. If the dimension D3 is greater than approximately 30 angstroms, the memory device 256 may not operate at lesser set voltages. If the dimension D3 is included in the range of approximately 8 angstroms to approximately 30 angstroms, a low set voltage to be used for the memory device 256 while enabling a low current leakage to be achieved for the memory device 256. However, other values for the dimension D3, and ranges other than approximately 8 angstroms to approximately 30 angstroms, are within the scope of the present disclosure.

As further shown in the close-up view of the layer stack of the memory device 256, the top electrode 308 may include a plurality of layers, such as a bottom nitride layer 308a over and/or on the resistive memory layer 306 (e.g., over and/or on the top resistive memory layer 306b), a metal layer 308b over and/or on the bottom nitride layer 308a, and/or a top nitride layer 308c over and/or on the metal layer 308b. The bottom nitride layer 308a includes a thin layer of tantalum nitride (TaN) and/or another metal nitride material. The metal layer 308b includes a layer of tantalum (Ta) and/or another metal material. The top nitride layer 308c includes another layer of tantalum nitride (TaN) and/or another metal nitride material.

The nitrogen concentration in the bottom nitride layer 308a and/or in the top nitride layer 308c may be selected to achieve a combination of a low set voltage for the memory device 256 and a low reset FBC for the memory device 256. In particular, the bottom nitride layer 308a and/or the top nitride layer 308c may be formed such that the nitrogen concentration in the bottom nitride layer 308a and/or in the top nitride layer 308c is included in a range of approximately 59% to approximately 62% by Auger electron spectroscopy analysis of the elemental composition of the bottom nitride layer 308a and/or the top nitride layer 308c to achieve a low set voltage for the memory device 256 and a low reset FBC for the memory device 256. If the nitride concentration is less than approximately 59%, the reset FBC for the memory device 256 may be too high. If the nitride concentration is greater than approximately 62%, the reset FBC for the memory device 256 may not operate at lesser set voltages. However, other ranges for the nitride concentration of the bottom nitride layer 308a and/or the top nitride layer 308c, and ranges other than approximately 59% to approximately 62% by Auger electron spectroscopy analysis of the material composition of the bottom nitride layer 308a and/or the top nitride layer 308c, are within the scope of the present disclosure.

As shown in a close-up view of the layer stack of the memory device 256, the top electrode 308 may have a dimension D4 corresponding to a thickness of the top electrode 304. In some implementations, the dimension D4 is included in a range of approximately 50 angstroms to approximately 150 angstroms. If the dimension D4 is less than approximately 50 angstroms, the memory device 256 may not operate at lesser set voltages. If the dimension D4 is greater than approximately 150 angstroms, the height or thickness of the memory device 256 may be unnecessarily increased. If the dimension D4 is included in the range of approximately 50 angstroms to approximately 150 angstroms, the height or thickness of the memory device 256 may enable the memory device 256 to be included in smaller form-factor semiconductor devices while enabling a low set voltage to be used for the memory device 256. However, other values for the dimension D4, and ranges other than approximately 50 angstroms to approximately 150 angstroms, are within the scope of the present disclosure.

As further shown in FIG. 3, the layer stack of the memory device 256 may be covered by one or more protective layers and/or structures. These protective layers and/or structures may be included to electrically insulate the memory device 256, to protect the memory device 256 from exposure to oxygen and other contaminants, and/or to thermally protect the memory device 256, among other examples. A hard mask layer 310 may be included over and/or on the top electrode 308. The hard mask layer 310 may surround the via 248 that is coupled with the top electrode 308. The hard mask layer 310 may include a silicon oxynitride (SiON), a silicon carbide (SiC), and/or another suitable dielectric mask material.

Sidewall spacers 312 may be included on sidewalls of the top electrode 308 and on sidewalls of the hard mask layer 310. The sidewall spacers may include a silicon nitride (SiₓN_{y} such as Si₃N₄), silicon carbide (SiC), and/or another dielectric spacer material. A nitride re-capping layer 314 may be included over the memory device 256. The nitride re-capping layer 314 may include a silicon nitride (SiₓN_{y} such as Si₃N₄) and/or another nitride-containing dielectric material. The nitride re-capping layer 314 may provide an etch stop layer for etching the recess in which the via 248 is formed.

As indicated above, FIG. 3 is provided as an example. Other examples may differ from what is described with regard to FIG. 3.

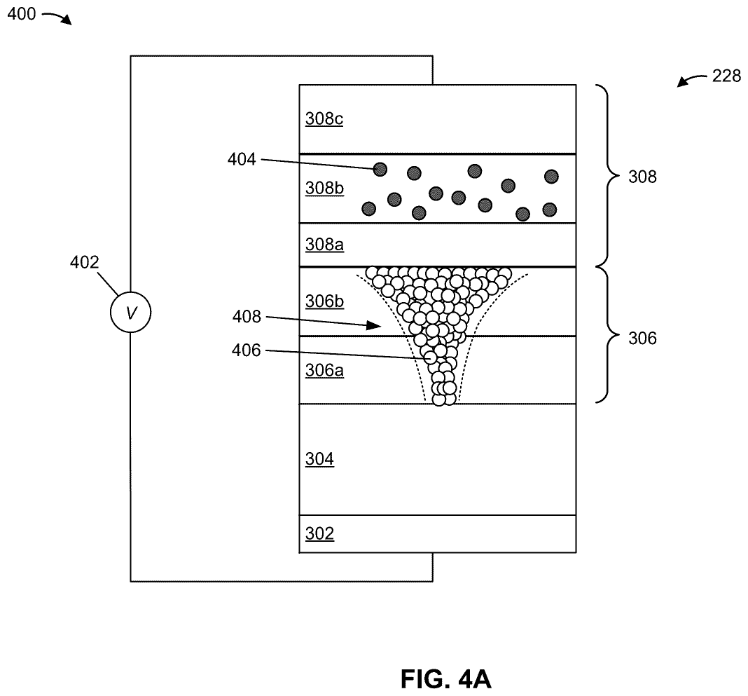

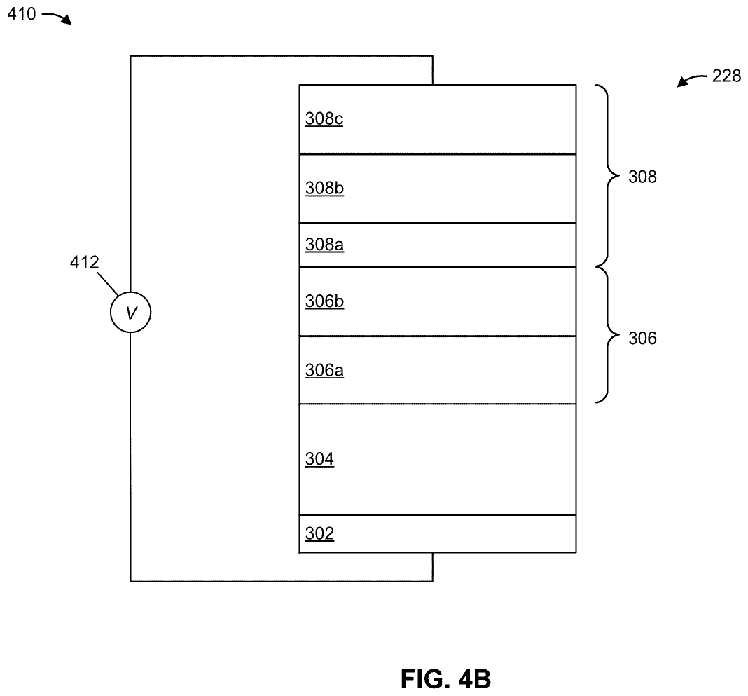

FIGS. 4A and 4B are diagrams illustrating example implementations of operations of the memory device 256 described herein. FIG. 4A illustrates an example implementation 400 of a set operation in which a conductive filament is formed in the memory device 256. FIG. 4B illustrates an example implementation 410 of a reset operation in which the conductive filament is removed from the memory device 256. The conductive filament may be selectively formed in the resistive memory layer 306 to selectively store one or more bits of electronic data based on an electrical resistance of the resistive memory layer 306.

As shown in FIG. 4A, the resistive memory layer 306 may be selectively set to an LRS to store a first logical value (e.g., a 0-value or a 1-value) by applying a set voltage 402 (also referred to as a forming voltage) across the top electrode 308 and the bottom electrode 304. The set voltage causes oxygen atoms 404 from the one or more layers 306a and/or 306b of the resistive memory layer 306 to be captured in one or more layers 308a-308c of the top electrode 308, resulting in formation of oxygen vacancies 406 in the one or more layers 306a and/or 306b of the resistive memory layer 306. An electric field from the set voltage 402 causes the oxygen vacancies 406 to form a conductive filament 408 through the resistive memory layer 306. The conductive filament 408 provides a path of electrical conductivity between the bottom electrode 304 and the top electrode 308 through the resistive memory layer 306.

As further shown in FIG. 4A, the cross-sectional profile of the conductive filament 408 may be tapered or curved between the bottom electrode 304 and the top electrode 308. The tapered or curved cross-sectional profile results in a conical (e.g., cone-shaped) three-dimensional shape for the conductive filament 408. In particular, the cross-sectional width of the conductive filament 408 may be greater at the top of the resistive memory layer 306 near the top electrode 308 than the cross-sectional width of the conductive filament 408 at the bottom of the resistive memory layer 306 near the bottom electrode 304. The cross-sectional width of the conductive filament 408 may decrease from the top of the resistive memory layer 306 to the bottom of the resistive memory layer 306.

The tapered cross-sectional profile (and the associated conical three-dimensional shape) of the conductive filament 408 results from the concentration of oxygen vacancies 406 being greater at the top of the resistive memory layer 306 than the concentration of oxygen vacancies 406 at the bottom of the resistive memory layer 306. In particular, the cross-sectional width of the conductive filament 408 may be greater at the top of the bottom resistive memory layer 306a than the cross-sectional width of the conductive filament 408 at the bottom of the bottom resistive memory layer 306a. This results from one or more of the high work function of the material of the bottom electrode 304, the hafnium to tantalum ratios in the bottom resistive memory layer 306a and the top resistive memory layer 306b, and/or from the low nitrogen concentration in the top electrode 308. In particular, the high work function of the material of the bottom electrode 304 results in a low oxygen affinity in the bottom electrode 304, which enables the bottom electrode 304 to resist oxygen absorption from the resistive memory layer 306. The lesser hafnium concentration in the bottom resistive memory layer 306a and the greater hafnium concentration in the top resistive memory layer 306b enable a greater concentration of oxygen vacancies to form in the top resistive memory layer 306b than in the bottom resistive memory layer 306a. The low nitrogen concentration in the top electrode 308 enables the top electrode 308 to more actively absorb oxygen from the resistive memory layer 306. The low oxygen absorption rate in the bottom electrode 304, the lesser oxygen vacancy concentration in the bottom resistive memory layer 306a than in the top resistive memory layer 306b, and/or the high oxygen absorption rate in the top electrode 308 enable the conical three-dimensional shape to be achieved for the conductive filament 408.

Moreover, the high oxygen absorption rate in the top electrode 308 enables a lesser set voltage 402 to be used in the set operation than if the nitrogen concentration were greater in the top electrode 308. For example, the high oxygen absorption rate in the top electrode 308 may enable a set voltage 402 of approximately 2 volts or less to be used to effectively form the conductive filament 408. However, other values for the set voltage 402 are within the scope of the present disclosure.

As shown in FIG. 4B, a reset voltage 412 may be applied across the bottom electrode 304 and the top electrode 308 to dissipate the conductive filament 408 in the resistive memory layer 306. The reset voltage 412 causes the oxygen atoms 404 captured in the top electrode 308 to recombine with the oxygen vacancies 406 in the resistive memory layer 306, resulting in a high electrical resistance in the resistive memory layer 306.

The tapered cross-sectional profile (and the associated conical three-dimensional shape) of the conductive filament 408 enables the oxygen vacancies 406 to be more effectively and fully removed from the resistive memory layer 306 than other cross-sectional and/or three-dimensional profiles for the conductive filament 408. For example, if an hour-glass three-dimensional shape were implemented in a conductive filament in a memory device (e.g., where the concentration of oxygen vacancies increases toward a top electrode and toward a bottom electrode of the memory device), the greater concentration of oxygen vacancies further down into the resistive memory layer results in difficulty in recombining those oxygen vacancies with oxygen atoms from the top electrode. This may result in residual oxygen vacancies in the resistive memory layer that, as set-reset cycles are accumulated for the memory device, may cause endurance issues and/or an increased reset FBC for the memory device. By forming a narrow conductive filament 408 at the bottom of the resistive memory layer 306 near the bottom electrode 304, as implemented in the tapered cross-sectional profile (and the associated conical three-dimensional shape) of the conductive filament 408 of the memory device 256, fewer oxygen vacancies 406 need to be removed from the bottom of the resistive memory layer 306 in order to dissipate the conductive filament 408. This results in a reduced likelihood that residual oxygen vacancies are accumulated in the resistive memory layer 306, which increases the endurance of the memory device 256 and/or decreases the reset FBC for the memory device 256, among other examples.

In this way, a lesser magnitude reset voltage may be used, which enables increased endurance to be achieved for the memory device 256. Alternatively, a reset voltage approximately matching the magnitude of the set voltage may be used due to improving oxygen and oxygen vacancy recombination by high work function for the bottom electrode 304, less nitrogen poison for top electrode 308, and/or improved Hf:TA ratios.

As indicated above, FIGS. 4A and 4B are provided as examples. Other examples may differ from what is described with regard to FIGS. 4A and 4B.

FIGS. 5A-5K are diagrams of an example implementation 500 of forming the memory device 256 described herein. In some implementations, one or more semiconductor processing tools 102-112 may be used to perform one or more of the semiconductor processing operations described in connection with FIGS. 5A-5K.

Turning to FIG. 5A, the memory device 256 may be formed in the BEOL region of the semiconductor device 200. The memory device 256 may be formed above the conductive structure 244 and/or another metallization layer in the BEOL region of the semiconductor device 200.

As shown in FIG. 5B, an opening may be formed through the ESL 220 to expose the top surface of the conductive structure 244. In some implementations, a pattern in a photoresist layer is used to etch the ESL 220 to form the opening through the ESL 220. In these implementations, a deposition tool may be used to form the photoresist layer on the ESL 220. An exposure tool may be used to expose the photoresist layer to a radiation source to pattern the photoresist layer. A developer tool may be used to develop and remove portions of the photoresist layer to expose the pattern. An etch tool may be used to etch the ESL 220 based on the pattern to form the opening through the ESL 220. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ESL 220 based on a pattern.

As shown in FIG. 5C, the layer stack of the memory device 256 is formed over and/or on the conductive structure 244. In some implementations, portions of the layer stack extend onto the ESL 220. In some implementations, these portions are subsequently removed.

FIG. 5D illustrates an example process for forming the layer stack of the memory device 256. As shown in FIG. 5D, at 502, the barrier layer 302 may be formed. The barrier layer 302 may be formed over and/or on the top surface of the conductive structure 244. A deposition tool may be used to deposit the barrier layer 302 using a PVD technique, an ALD technique, a CVD technique, an oxidation technique, and/or another suitable deposition technique.

As further shown in FIG. 5D, at 504, the bottom electrode 304 is formed. The bottom electrode 304 may be formed over and/or on the barrier layer 302. A deposition tool may be used to deposit the bottom electrode 304 using a CVD technique, a PVD technique, an ALD technique, an electroplating technique, and/or another suitable technique operation.

As further shown in FIG. 5D, at 506, the bottom resistive memory layer 306a is formed. The bottom resistive memory layer 306a may be formed over and/or on the bottom electrode. A deposition tool may be used to deposit the bottom resistive memory layer 306a using a PVD technique, an ALD technique, a CVD technique, an oxidation technique, and/or another suitable deposition technique.

As further shown in FIG. 5D, at 508, the top resistive memory layer 306b is formed. The top resistive memory layer 306b may be formed over and/or on the bottom resistive memory layer 306a. A deposition tool may be used to deposit the top resistive memory layer 306b using a PVD technique, an ALD technique, a CVD technique, an oxidation technique, and/or another suitable deposition technique.

The bottom resistive memory layer 306a may be formed of a first resistive memory material, and the top resistive memory layer 306b may be formed of a second resistive memory material. The bottom resistive memory layer 306a may be formed such that the first resistive memory material has a first hafnium concentration, and the top resistive memory layer 306b may be formed such that the second resistive memory material has a second hafnium concentration that is greater than the first hafnium concentration. In some implementations, the bottom resistive memory layer 306a is formed by performing a first ALD operation to achieve the first hafnium concentration in the first resistive memory material, and the top resistive memory layer 306b is formed by performing a second ALD operation to achieve a second hafnium concentration in the second resistive memory material. The first ALD operation is performed such that atomic layers of hafnium and tantalum are deposited in a highly precise and controlled manner to achieve the first hafnium concentration in the first resistive memory material, and the second ALD operation is performed such that atomic layers of hafnium and tantalum are deposited in a highly precise and controlled manner to achieve the second hafnium concentration in the second resistive memory material.

As further shown in FIG. 5D, at 510-514, the top electrode 308 is formed over and/or on the resistive memory layer 306. The deposition tool 102 may be used to form the top electrode 308 using a PVD technique such as a sputter deposition technique. Forming the top electrode 308 includes positioning the semiconductor device 200 on the chuck 108 in the processing chamber 104 of the deposition tool 102. A material target 110 (e.g., a tantalum (Ta) target material) is also included in the processing chamber 104. A process gas 114 (e.g., a nitrogen (N) process gas) is provided into the processing chamber 104, and a plasma 112 is generated in the processing chamber 104. Ions in the plasma 112 are accelerated toward the material target 110 to generate a sputtered material 116 that is deposited onto the semiconductor device 200. The initial flow-in of the process gas 114 reacts with the sputtered material 116 and results in the deposition of the bottom nitride layer 308a on the resistive memory layer 306. Once the process gas 114 stabilizes in the processing chamber 104, the sputtered material 116 deposits onto the semiconductor device 200 as the metal layer 308b on the bottom nitride layer 308a. A flow rate of the process gas 114 is then increased such that the process gas 114 again reacts with the sputtered material 116 and results in the deposition of the top nitride layer 308c on the metal layer 308b.

The process gas 114 is provided into the processing chamber 104 at a flow rate that promotes a reaction between the process gas 126 and the sputtered material 116 when depositing the top nitride layer 308c, and resists a reaction between the process gas 126 and the material target 110. If the flow rate of the process gas 114 into the processing chamber 104 is too high, a reaction occurs between the process gas 114 and the material target 110 in which the process gas 114 poisons the material target 110. The poisoning of the material target 110 results in a reduced ability to control the nitrogen concentration in the top nitride layer 308c of the top electrode 308.

In some implementations, the flow rate of the process gas 114 into the processing chamber 104 may be controlled to be included in a range of approximately 20 standard cubic centimeters per minute (sccm) to approximately 75 sccm. If the flow rate is outside of this range, the process gas 114 may poison the material target 110, which may result in too high of a nitrogen concentration in the top electrode 308. As a result, the top electrode 308 may not be sufficiently active in absorbing oxygen atoms from the resistive memory layer 306, and the memory device 256 may not be operable at lesser set voltages as a result. If the flow rate is included in a range of approximately 20 sccm to approximately 75 sccm, the top electrode 308 may be formed to include a nitrogen concentration in the bottom nitride layer 308a and/or in the top nitride layer 308c that is in a range of approximately 59% to approximately 62% by Auger electron spectroscopy analysis of the elemental composition of the bottom nitride layer 308a and/or the top nitride layer 308c. This enables a low set voltage to be achieved for the memory device 256 and a low reset FBC to be achieved for the memory device 256. However, other values for the flow rate of the process gas 114, and ranges other than approximately 20 sccm to approximately 75 sccm, are within the scope of the present disclosure.

As shown in FIG. 5E, the hard mask layer 310 may be formed over and/or on the layer stack of the memory device 256. A deposition tool may be used to deposit the hard mask layer 310 using a PVD technique, an ALD technique, a CVD technique, an oxidation technique, and/or another suitable deposition technique. In some implementations, a planarization tool may be used to planarize the hard mask layer 310.

As shown in FIG. 5F, portions of the hard mask layer 310 and portions of the top electrode 308 may be removed to expose portions of the top surface of the resistive memory layer 306. In some implementations, a pattern in a photoresist layer is used to etch the hard mask layer 310 and the resistive memory layer 306. In these implementations, a deposition tool may be used to form the photoresist layer on the hard mask layer 310. An exposure tool may be used to expose the photoresist layer to a radiation source to pattern the photoresist layer. A developer tool may be used to develop and remove portions of the photoresist layer to expose the pattern. An etch tool may be used to etch the hard mask layer 310 and the resistive memory layer 306 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the hard mask layer 310 and the resistive memory layer 306 based on a pattern.

As shown in FIG. 5G, sidewall spacers 312 are formed in areas in which the portions of the hard mask layer 310 and the top electrode 308 were removed. A deposition tool may be used to deposit the sidewall spacers 312 using a PVD technique, an ALD technique, a CVD technique, an oxidation technique, and/or another suitable deposition technique.

As shown in FIG. 5H, the nitride re-capping layer 314 is formed over and/or on the hard mask layer 310 and the sidewall spacers 312. The nitride re-capping layer 314 is also formed on sidewalls of the barrier layer 302, the bottom electrode 304, and/or the resistive memory layer 306. A deposition tool may be used to deposit the nitride re-capping layer 314 using a PVD technique, an ALD technique, a CVD technique, an oxidation technique, and/or another suitable deposition technique.

As shown in FIG. 5I, the dielectric layer 222 is formed over and/or on the memory device 256. A deposition tool may be used to deposit the dielectric layer 222 using a PVD technique, an ALD technique, a CVD technique, an oxidation technique, and/or another suitable deposition technique. In some implementations, a planarization tool may be used to planarize the dielectric layer 222.

As shown in FIG. 5J, a recess 516 is formed through the dielectric layer 222, through the nitride re-capping layer 314, and through the hard mask layer 310. The recess 516 is formed over the memory device 256 such that the top surface of the top electrode 308 is exposed through the recess 516. In some implementations, a pattern in a photoresist layer is used to etch through the dielectric layer 222, through the nitride re-capping layer 314, and through the hard mask layer 310. In these implementations, a deposition tool may be used to form the photoresist layer on the dielectric layer 222. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 222, through the nitride re-capping layer 314, and through the hard mask layer 310 based on the pattern. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 516 based on a pattern.

In some implementations, the recess 516 includes a dual damascene recess that includes a via portion and a trench portion. In some implementations, a trench-first process is performed in which the trench portion is formed, followed by formation of the via portion. In some implementations, a via-first process is performed in which the via portion is formed, followed by formation of the trench portion.

As shown in FIG. 5K, the via 248 and the conductive structure 252 may be formed in the recess 516. The via 248 may be electrically coupled and/or physically coupled with the top electrode 308 of the memory device 256. A deposition tool may be used to deposit the via 248 and the conductive structure 252 using a CVD technique, a PVD technique, an ALD technique, an electroplating technique, and/or another suitable technique operation. In some implementations, a planarization tool may be used to planarize the conductive structure 252.

As indicated above, 5A-5K is provided as an example. Other examples may differ from what is described with regard to 5A-5K.

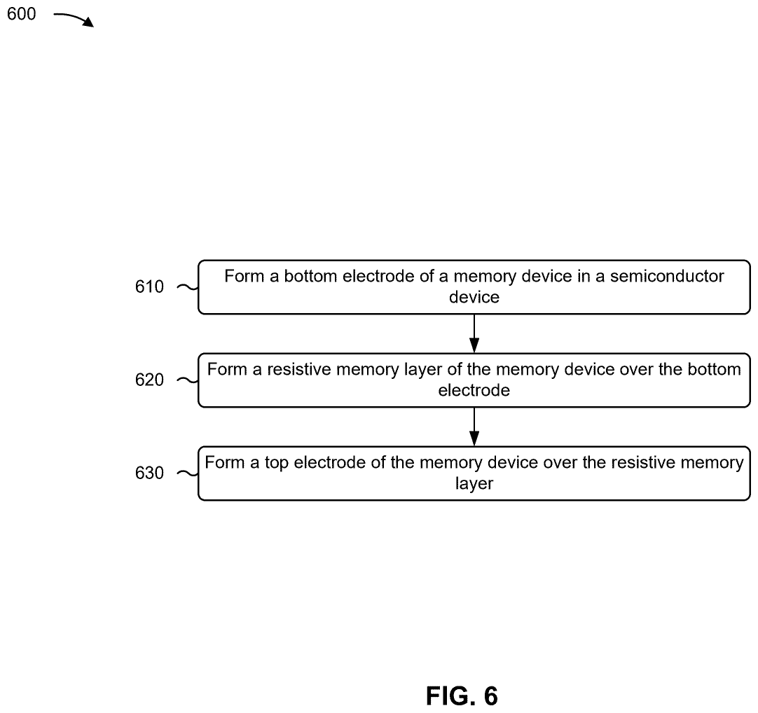

FIG. 6 is a flowchart of an example process 600 associated with forming a semiconductor device described herein. In some implementations, one or more process blocks of FIG. 6 are performed using one or more semiconductor processing tools, such as the deposition tool 102, among other examples.

As shown in FIG. 6, process 600 may include forming a bottom electrode of a memory device in a semiconductor device (block 610). For example, one or more semiconductor processing tools may be used to form a bottom electrode 304 of a memory device 256 in a semiconductor device 200, as described herein. In some implementations, the bottom electrode 304 is formed of a chemically inert electrically conductive material having a work function that is greater than a work function of ruthenium (Ru).

As further shown in FIG. 6, process 600 may include forming a resistive memory layer of the memory device over the bottom electrode (block 620). For example, one or more semiconductor processing tools may be used to form a resistive memory layer (e.g., a resistive memory layer 306, a bottom resistive memory layer 306a, a top resistive memory layer 306b) of the memory device 256 over the bottom electrode 304, as described herein.

As further shown in FIG. 6, process 600 may include forming a top electrode of the memory device over the resistive memory layer (block 630). For example, one or more semiconductor processing tools (e.g., the deposition tool 102) may be used to form a top electrode (e.g., a top electrode 308, a bottom nitride layer 308a, a metal layer 308b, a top nitride layer 308c) of the memory device 256 over the resistive memory layer, as described herein.

Process 600 may include additional implementations, such as any single implementation or any combination of implementations described below and/or in connection with one or more other processes described elsewhere herein.

In a first implementation, the chemically inert electrically conductive material includes molybdenum nitride (MoN).

In a second implementation, alone or in combination with the first implementation, the chemically inert electrically conductive material includes tungsten nitride (WN).

In a third implementation, alone or in combination with one or more of the first and second implementations, forming the resistive memory layer includes forming a first high-k dielectric layer (e.g., a bottom resistive memory layer 306a), of the resistive memory layer, on the bottom electrode 304, and forming a second high-k dielectric layer (e.g., a top resistive memory layer 306b), of the resistive memory layer, on the first high-k dielectric layer, where a second hafnium (Hf) concentration in the second high-k dielectric layer is greater than a first hafnium concentration in the first high-k dielectric layer.

In a fourth implementation, alone or in combination with one or more of the first through third implementations, forming the first high-k dielectric layer includes performing a first ALD operation to achieve the first hafnium concentration in the first high-k dielectric layer, and forming the second high-k dielectric layer includes performing a second ALD operation to achieve the second hafnium concentration in the second high-k dielectric layer.

In a fifth implementation, alone or in combination with one or more of the first through fourth implementations, the second high-k dielectric layer includes a second hafnium:tantalum (Hf:Ta) ratio that is greater than a first hafnium:tantalum ratio of the first high-k dielectric layer.

In a sixth implementation, alone or in combination with one or more of the first through fifth implementations, forming the bottom electrode 304 includes forming the bottom electrode 304 to a thickness that is included in a range of approximately 30 angstroms to approximately 100 angstroms.

In a seventh implementation, alone or in combination with one or more of the first through sixth implementations, forming the top electrode includes using the deposition tool 102 to generate a sputtered material 116 from a material target 110 in the processing chamber 104 to deposit the sputtered material 116 to form the top electrode, where the nitrogen gas is provided into the processing chamber 104 at a flow rate that promotes a reaction between the nitrogen gas and the sputtered material 116, and resists a reaction between the nitrogen gas and the material target 110.

In an eighth implementation, alone or in combination with one or more of the first through seventh implementations, the flow rate of the nitrogen gas is included in a range of approximately 20 sccm to approximately 75 sccm.

In a ninth implementation, alone or in combination with one or more of the first through eighth implementations, forming the top electrode includes depositing a first tantalum nitride (TaN) layer (e.g., a bottom nitride layer 308a) on the resistive memory layer, depositing a tantalum (Ta) layer (e.g., a metal layer 308b) on the first tantalum nitride layer, and depositing a second tantalum nitride layer (e.g., a top nitride layer 308c) on the tantalum layer, where the nitrogen gas is provided into the processing chamber 104 at the flow rate that promotes the reaction between the nitrogen gas and the sputtered material 116, and resists the reaction between the nitrogen gas and the material target 110 when depositing the second tantalum nitride layer.

In a tenth implementation, alone or in combination with one or more of the first through ninth implementations, forming the top electrode includes forming the top electrode to a thickness that is included in a range of approximately 50 angstroms to approximately 150 angstroms.

In an eleventh implementation, alone or in combination with one or more of the first through tenth implementations, forming the bottom electrode 304 includes forming the bottom electrode 304 of an electrically conductive material having a work function that is included in a range of approximately 4.9 to approximately 5.3.

In a twelfth implementation, alone or in combination with one or more of the first through eleventh implementations, the process 600 includes forming a conductive filament 408 through the resistive memory layer, where the cross-sectional width of the conductive filament 408 may be greater at the top of the resistive memory layer than the cross-sectional width of the conductive filament 408 at the bottom of the bottom resistive memory layer.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In this way, an RRAM cell includes a bottom electrode that includes a high work function material. The high work function material enables the work function of the bottom electrode to be tuned such that a thinner and more conical conductive filament is formed in a resistive memory layer stack of the RRAM cell than without the high work function material. The conductive filament being thinner than without the high work function material enables the conductive filament to be formed using fewer oxygen vacancies than without the high work function material, which reduces the difficulty of combining oxygen vacancies in the resistive memory layer stack with oxygen atoms captured in a top electrode of the RRAM cell. Additionally and/or alternatively the conical shape of the conductive filament results from fewer oxygen vacancies near the bottom electrode, which further reduces difficulty of combining oxygen vacancies in the resistive memory layer stack with oxygen atoms captured in a top electrode of the RRAM cell in that the oxygen atoms do not need to travel as far down into the resistive memory layer stack. Accordingly, the high work function material of the bottom electrode described herein enables a more complete oxygen recombination to be achieved during a reset operation of the RRAM cell.

As described in greater detail above, some implementations described herein provide a method. The method includes forming a bottom electrode of a memory device in a semiconductor device, where the bottom electrode is formed of a chemically inert electrically conductive material having a work function that is greater than a work function of ruthenium (Ru). The method includes forming a resistive memory layer of the memory device over the bottom electrode. The method includes forming a top electrode of the memory device over the resistive memory layer.

As described in greater detail above, some implementations described herein provide a memory device. The memory device includes a bottom electrode. The memory device includes a resistive memory layer stack on the bottom electrode. The resistive memory layer stack includes a first resistive memory layer including a first resistive memory material, and a second resistive memory layer including a second resistive memory material. A second ratio of a high-k dielectric concentration to a metal concentration in the second resistive memory material is greater than a first ratio of a high-k dielectric concentration to a metal concentration in the first resistive memory material. The memory device includes a top electrode on the resistive memory layer stack.

As described in greater detail above, some implementations described herein provide a method. The method includes forming a bottom electrode of a memory device in a semiconductor device. The method includes forming a resistive memory layer of the memory device over the bottom electrode. The method includes forming a top electrode of the memory device over the resistive memory layer. Forming the top electrode includes providing a nitrogen gas into a processing chamber of a deposition tool and generating a sputtered material from a material target in the processing chamber to deposit the sputtered material to form the top electrode, where the nitrogen gas is provided into the processing chamber at a flow rate that promotes a reaction between the nitrogen gas and the sputtered material, and resists a reaction between the nitrogen gas and the material target.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a bottom electrode of a memory device in a semiconductor device,
wherein the bottom electrode is formed of a chemically inert electrically conductive material having a work function that is greater than a work function of ruthenium (Ru);
forming a resistive memory layer of the memory device over the bottom electrode; and
forming a top electrode of the memory device over the resistive memory layer.

2. The method of claim 1, wherein the chemically inert electrically conductive material comprises molybdenum nitride (MoN).

3. The method of claim 1, wherein the chemically inert electrically conductive material comprises tungsten nitride (WN).

4. The method of claim 1, wherein forming the resistive memory layer comprises:
forming a first high dielectric constant (high-k) dielectric layer, of the resistive memory layer, on the bottom electrode; and
forming a second high-k dielectric layer, of the resistive memory layer, on the first high-k dielectric layer,
wherein a second hafnium (Hf) concentration in the second high-k dielectric layer is greater than a first hafnium concentration in the first high-k dielectric layer.

5. The method of claim 4, wherein forming the first high-k dielectric layer comprises:
performing a first atomic layer deposition (ALD) operation to achieve the first hafnium concentration in the first high-k dielectric layer; and
wherein forming the second high-k dielectric layer comprises:
performing a second ALD operation to achieve the second hafnium concentration in the second high-k dielectric layer.

6. The method of claim 4, wherein the second high-k dielectric layer comprises a second hafnium:tantalum (Hf:Ta) ratio that is greater than a first hafnium: tantalum ratio of the first high-k dielectric layer.

7. The method of claim 1, wherein forming the bottom electrode comprises:
forming the bottom electrode to a thickness that is included in a range of approximately 30 angstroms to approximately 100 angstroms.

8. A memory device, comprising:
a bottom electrode;
a resistive memory layer stack, on the bottom electrode, comprising:
a first resistive memory layer comprising a first resistive memory material; and
a second resistive memory layer comprising a second resistive memory material,
wherein a second ratio of a high dielectric constant (high-k) dielectric concentration to a metal concentration in the second resistive memory material is greater than a first ratio of a high-k dielectric concentration to a metal concentration in the first resistive memory material; and
a top electrode on the resistive memory layer stack.

9. The memory device of claim 8, wherein the bottom electrode comprises an electrically conductive material having a work function that is included in a range of approximately 4.9 to approximately 5.3.

10. The memory device of claim 8, wherein a nitrogen concentration, in an elemental composition of a material of the top electrode, is included in a range of approximately 59% of the elemental composition to approximately 62% of the elemental composition.

11. The memory device of claim 8, wherein the first ratio of the high-k dielectric concentration to the metal concentration in the first resistive memory material is included in a range of approximately 1:3 to approximately 1:6.

12. The memory device of claim 8, wherein the bottom electrode comprises at least one of:
molybdenum nitride (MoN), or
tungsten nitride (WN).

13. The memory device of claim 8, wherein the top electrode comprises:
a first tantalum nitride (TaN) layer on the resistive memory layer stack;
a tantalum (Ta) layer on the first tantalum nitride layer; and
a second tantalum nitride layer on the tantalum layer.

14. The memory device of claim 8, wherein the first resistive memory layer and the second resistive memory layer each have a thickness that is included in a range of approximately 8 angstroms to approximately 30 angstroms.

15. A method, comprising:
forming a bottom electrode of a memory device in a semiconductor device,
forming a resistive memory layer of the memory device over the bottom electrode; and
forming a top electrode of the memory device over the resistive memory layer,
wherein forming the top electrode comprises:
providing a nitrogen gas into a processing chamber of a deposition tool; and
generating a sputtered material from a material target in the processing chamber to deposit the sputtered material to form the top electrode,
wherein the nitrogen gas is provided into the processing chamber at a flow rate that promotes a reaction between the nitrogen gas and the sputtered material, and resists a reaction between the nitrogen gas and the material target.

16. The method of claim 15, wherein the flow rate of the nitrogen gas is included in a range of approximately 20 standard cubic centimeters per minute (sccm) to approximately 75 sccm.

17. The method of claim 15, wherein forming the top electrode comprises:
depositing a first tantalum nitride (TaN) layer on the resistive memory layer;
depositing a tantalum (Ta) layer on the first tantalum nitride layer; and
depositing a second tantalum nitride layer on the tantalum layer,
wherein the nitrogen gas is provided into the processing chamber at the flow rate that promotes the reaction between the nitrogen gas and the sputtered material, and resists the reaction between the nitrogen gas and the material target when depositing the second tantalum nitride layer.

18. The method of claim 15, wherein forming the top electrode comprises:
forming the top electrode to a thickness that is included in a range of approximately 50 angstroms to approximately 150 angstroms.

19. The method of claim 15, wherein forming the bottom electrode comprises:
forming the bottom electrode of at least one of:
molybdenum nitride (MoN), or
tungsten nitride (WN).

20. The method of claim 15, further comprising: further comprising:
forming a conductive filament through the resistive memory layer,
wherein the cross-sectional width of the conductive filament may be greater at the top of the resistive memory layer than the cross-sectional width of the conductive filament at the bottom of the resistive memory layer.
